(19) United States
(12) Patent Application Publication
(10) Pub. No.: US 2020/0019853 A1
(43) Pub. Date: Jan. 16, 2020

(54) PRODUCT TESTING SYSTEM WITH AUXILIARY JUDGING FUNCTION AND AUXILIARY TESTING METHOD APPLIED THERETO

(71) Applicant: Primax Electronics Ltd., Taipei (TW)

(72) Inventors: Shih-Chieh Hsu, Taipei (TW); Pei-Ming Chang, Taipei (TW); Pao-Chung Chao, Taipei (TW); Wei-Lung Huang, Taipei (TW)

(21) Appl. No.: 16/192,040

(22) Filed: Nov. 15, 2018

(30) Foreign Application Priority Data
Jul. 13, 2018 (TW) 107124305

(51) Int. Cl. G06N 3/08; H05K 13/08; G05B 19/401; G01C 25/00; G01P 21/00

(52) U.S. Cl. CPC G06N 3/08; H05K 13/083; G01P 21/00; G01C 25/00; G05B 19/401

(57) ABSTRACT

A product testing system and an auxiliary testing method are provided. The product testing system includes a computer and a test fixture. The computer has a machine learning model. The auxiliary testing method includes the following steps. Firstly, the test fixture tests the plural under-test products sequentially, and generates corresponding test data to the computer. Then, the computer generates plural trend line graphs corresponding to the test data. Then, the operator determines corresponding human judging results according to the trend line graphs. The test data, the trend line graphs and the human judging results are inputted into the machine learning model, and a learning process is performed. If the number of samples reaches a predetermined threshold value, the machine learning model generates auxiliary judging results according to the corresponding test data and the corresponding trend line graphs.

### FIELD OF THE INVENTION

The present invention relates to a product testing system with an auxiliary judging function and an auxiliary testing method, and more particularly to a system and a method of using a machine learning mode to generate a prediction result as an objective reference in addition to the subjective judgment of the operator, so that the working time is reduced and the misjudgment is avoided.

### BACKGROUND OF THE INVENTION

With increasing development of science and technology, various electronic products such as 3C electronic devices are widely used in daily lives of people. In the modern electronic factories, electronic products have to be tested before the electronic products leave the factories. In addition to an in-circuit test, the electronic products have to undergo a functional circuit test prior to shipment. The in-circuit test is a circuitry test or an electrical property test for complying with the electric safety regulations. In accordance with the conventional technologies, the functional circuit test uses a relevant testing program to calculate its trend line graph to understand the quality of the product.

For example, the widely-used motion sensors for sensing motions include gyroscopes, accelerometer sensors, or the like. The accelerometer sensor is used for sensing the directions of the acceleration. The gyroscope is used for sensing the angular velocities. For testing the functions of the motion sensor in the production line, the motion sensor is placed on a test platform of a test fixture. Moreover, the test fixture creates a three-dimensional motion (e.g., the motion including a translation and a rotation) on the test platform. According to the sensing result of the motion sensor at different angles, a trend line graph is generated. By observing the trend line graph, the function of the motion sensor can be realized.

FIGS. 1A and 1B are trend line graphs illustrating the results of the functional circuit tests about two different sensors. After the operator in the production line observes the two trend line graphs according to the subjective judgment, the testing results of the sensors are determined. For example, the testing result of FIG. 1A indicates that the sensor is qualified and the sensor passes the test. The testing result of FIG. 1B indicates that the sensor is unqualified and the sensor fails in the test. In the two drawings, the horizontal axis represents the angle of rotation and the vertical axis represents the measured torque (unit: Newton meter).

As mentioned above, the testing results of the sensors are determined according to the experience of the operator. If the trend line graph indicates that the torque increases slowly with the increasing rotation angle, the sensor is qualified and the sensor passes the test (see FIG. 1A). If the trend line graph indicates that the torque does not increase slowly with the increasing rotation angle, the sensor is unqualified and the sensor fails in the test (see FIG. 1B). Of course, the trend line graph corresponding to the unqualified product is not restricted to the graph of FIG. 1B.

However, if a large number of products need to be tested or a large number of items need to be tested, some problems occur. For example, the operator has to spend a lot of time in processing the collected data and observing and judging a large number of trend line graphs. Consequently, the manpower burden is very large. Even if the classification about the qualified product (Pass) and the unqualified product (Fail) is simple, the huge workload may result in misjudgment of the operator. Moreover, even if the classification criteria are objective, the observation and judgment are still subjective. If the details of the generated trend line graph are difficult to be distinguished, the trend line graph cannot be accurately judged by the operator.

Therefore, there is a need of providing an auxiliary system for testing a large number of products in the production line and assisting the operator to judge the testing results in order to reduce the possibility of misjudgment, reduce the working time and reduce the fabrication cost.

### SUMMARY OF THE INVENTION

The present invention provides a product testing system with an auxiliary judging function and an auxiliary testing method. In the product testing system and the auxiliary testing method, a machine learning model is used for providing an auxiliary judging function in the testing process. That is, the operator in the production line observes and subjectively judges the trend line graphs. Moreover, after the machine learning model is trained and learnt through a specified algorithm, the judging result with the artificial intelligence feature is generated to be used as a reference for the operator. Consequently, even if the testing process needs a large amount of working time and huge workload, the assistance of the machine learning model is helpful to avoid misjudgment and differentiate the details.

In accordance with an aspect of the present invention, there is provided an auxiliary testing method for a product testing system and plural under-test products. The product testing system includes a computer and a test fixture. The computer is in communication with the test fixture. The computer has a machine learning model. The auxiliary testing method includes the following steps. Firstly, the test fixture tests the plural under-test products sequentially, and generates corresponding test data to the computer. Then, the computer generates plural trend line graphs corresponding to the test data. Then, the operator judges the contents of the trend line graphs, and determines corresponding human judging results. The test data, the trend line graphs and the human judging results are inputted into the machine learning model, and a learning process is performed. If the number of samples in the learning process reaches a predetermined threshold value, the machine learning model generates auxiliary judging results according to the corresponding test data and the corresponding trend line graphs.

In accordance with another aspect of the present invention, there is provided a product testing system with an auxiliary judging function and configured for testing plural under-test products. The product testing system includes a test fixture and a computer. The test fixture tests the plural under-test products sequentially, and generates corresponding test data. The computer is in communication with the test fixture. The computer has a machine learning model that receives the test data from the test fixture and generates plural trend line graphs corresponding to the test data. After an operator judges contents of the trend line graphs and determines corresponding human judging results, the test data, the trend line graphs and the human judging results are inputted into the machine learning model and a learning process is performed. When the number of samples in the learning process reaches a predetermined threshold value, the machine learning model generates auxiliary judging results according to the corresponding test data and the corresponding trend line graphs.

The above objects and advantages of the present invention will become more readily apparent to those ordinarily skilled in the art after reviewing the following detailed description and accompanying drawings, in which:

### BRIEF DESCRIPTION OF THE DRAWINGS

FIGS. 1A and 1B are trend line graphs illustrating the results of the functional circuit tests about two different sensors;

FIG. 2 is a schematic functional block diagram illustrating a product testing system according to an embodiment of the present invention;

FIG. 3 schematically illustrates the architecture of a neural network; and

FIG. 4 schematically illustrates an auxiliary testing method according to an embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. In the following embodiments and drawings, the elements irrelevant to the concepts of the present invention are omitted and not shown.

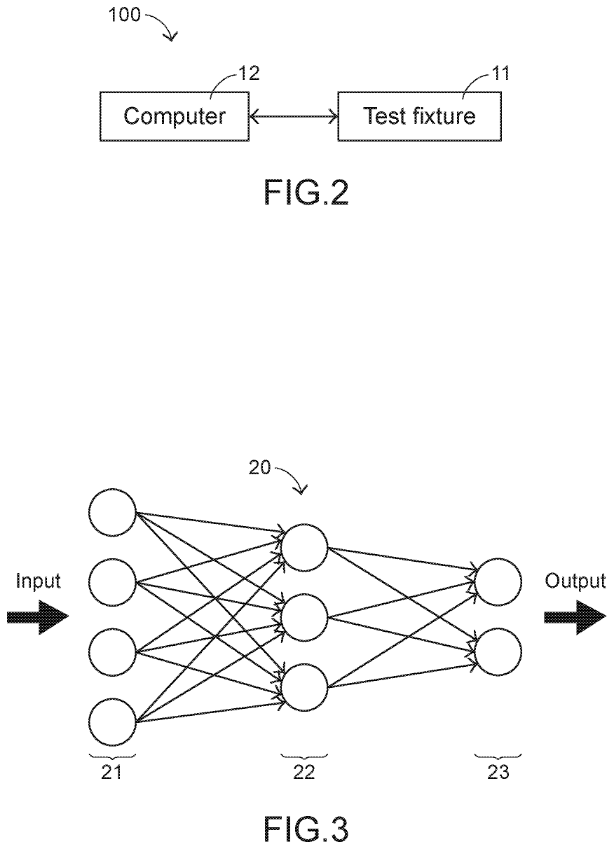

Hereinafter, the examples of a product testing system with an auxiliary judging function and an auxiliary testing method will be illustrated with reference to FIG. 2. FIG. 2 is a schematic functional block diagram illustrating a product testing system according to an embodiment of the present invention. As shown in FIG. 2, the product testing system 100 comprises a computer 12 and a test fixture 11. The computer 12 is in communication with the test fixture 11. A machine learning model is loaded in the computer 12. The test fixture 11 is used for testing plural under-test products (not shown).

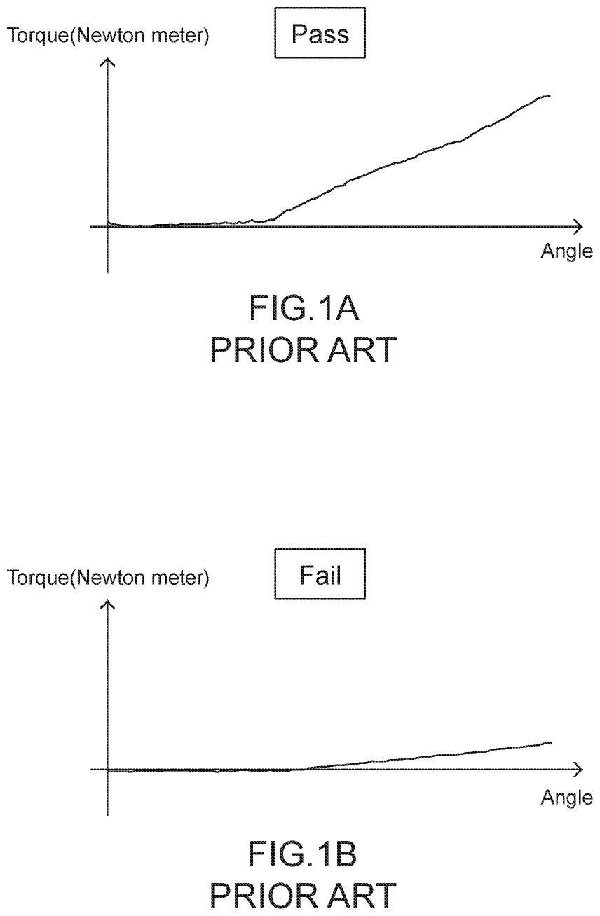

In an embodiment, the under-test products are motion sensors. The test fixture 11 can test the three-dimensional motions of the motion sensors. It is noted that the examples of the under-test products are not restricted. The computer 12 implements a functional test task. For example, before the electronic product in a production line leaves the factory, the computer 12 tests various functions of the electronic product to recognize the quality of the electronic product. Like the conventional technology, a testing program is installed in the computer 12. When the testing program is executed, the trend line graph of the under-test product as shown in FIGS. 1A and 1B is calculated. Consequently, the computer 12 can judge whether the function of the under-test product is normal.

In accordance with a feature of the present invention, the machine learning model is used for providing an auxiliary judging function in the testing process. That is, the operator in the production line observes and subjectively judges the trend line graphs. Moreover, after the machine learning model is trained and learnt through a specified algorithm, the judging result with the artificial intelligence feature is generated to be used as a reference for the operator. Consequently, even if the testing process needs a large amount of working time and huge workload, the assistance of the machine learning model is helpful to avoid misjudgment and differentiate the details.

An example of the machine learning model includes but is not limited to a neural network model or an artificial neural network model. According to the existing technology, the neural network is an artificial intelligence system that uses computers to simulate biological brain nerves. The neural network has the learning, memorizing and inducting characteristics, and has the identifying, judging, controlling or predicting function.

FIG. 3 schematically illustrates the architecture of a neural network. The neural network 20 has three parts, including neurons (or nodes), layers and a network. The neural network 20 comprises plural neurons, which are denoted as circles. The neurons are connected with each other to define plural layers through weights. The neurons of each layer are connected with the neurons of the previous layer and the neurons of the next layer. The neural network 20 as shown in FIG. 3 is a three-layered structure. The neural network 20 comprises an input layer 21, a hidden layer 22 and an output layer 23. The neurons are distributed in the three layers and connected with each other to constitute the whole network.

The input layer 21 receives the input data or information from the outside of the neural network 20. The neurons of the input layer 21 transfer the data or information to the next layer. The hidden layer 22 is arranged between the input layer 21 and the output layer 23. After the neutrons of the hidden layer 22 analyzes the input data or information, the hidden layer 22 provides a function to connect the variables of the input layer 21 and the variables of the output layer 23 to fit the data. The analyzed result is outputted from the output layer 23 to the outside of the neural network 20. Particularly, each layer of the neural network 20 comprises plural neurons. The neurons of different layers are connected with each other through connection lines. Each connection line denotes a neuron connection weight. Moreover, each neuron includes a transfer function or an activation function. After the input value is calculated according to the transfer function or the activation function, the output value is generated.

Generally, the training process or the leaning process of the neural network includes two stages, including a forward-propagation stage and a backward-propagation stage. In the forward-propagation stage, the machine learning model analyzes the acquired data and generates a prediction result. According to dichotomy or polarization, the prediction result is the weight corresponding to “0” or “1”, “yes” or “no”, or “can” or “cannot”. In the backward-propagation stage, the operator or the engineer notifies the machine learning model of the difference between the prediction result and the real result. After the error is corrected and backwardly propagated, the weight of each neutron is correspondingly adjusted. Consequently, when the machine learning model is in the similar condition, the prediction result is close to the real result or the successful judging probability is enhanced.

In the above embodiment, the machine learning model uses the architecture of the neural network as shown in FIG. 3. It is noted that the architecture of the neural network is not restricted. For example, the neural network as shown in FIG. 3 contains one hidden layer 22. In another embodiment, the neural network contains plural hidden layers (e.g., two hidden layers). Alternatively, the number of neutrons in each layer may be determined according to the practical requirements. Alternatively, the machine learning model uses any appropriate algorithm or model. For example, the machine learning model uses a support vector machines (SVM) model.

In accordance with a feature of the present invention, the testing process generates a non-linear testing result, and the non-linear testing result is further processed by the machine learning mode. In the training and learning process, sufficient data are inducted and converged, and thus the output result is close to the desired target value. The auxiliary testing method for the product testing system will be described as follows.

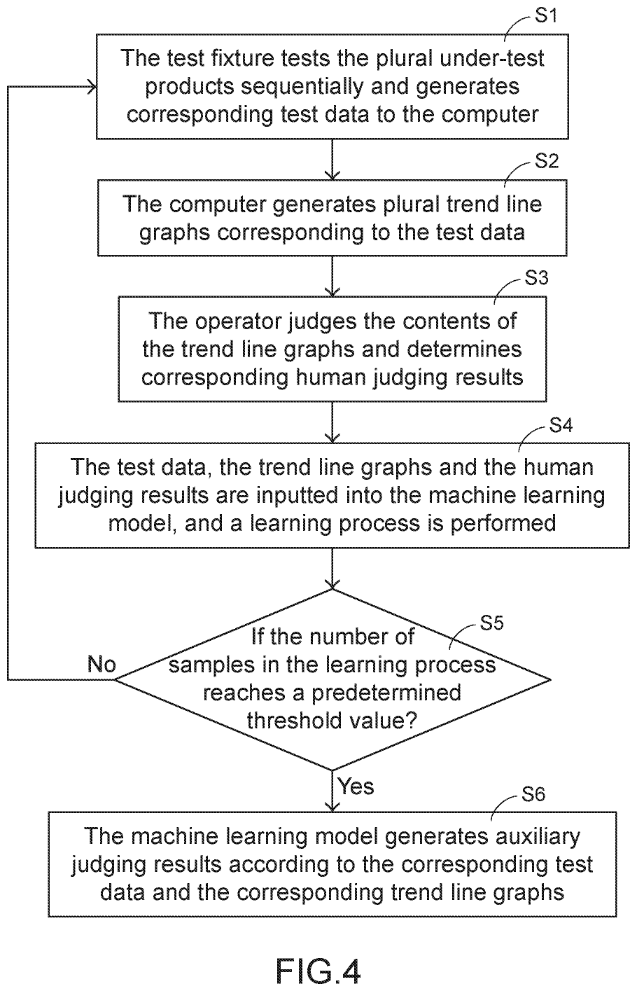

FIG. 4 schematically illustrates an auxiliary testing method according to an embodiment of the present invention. Firstly, the test fixture 11 tests the plural under-test products sequentially and generates corresponding test data to the computer 12 (Step S1). Then, the computer 12 generates plural trend line graphs corresponding to the test data (Step S2). Then, the operator judges the contents of the trend line graphs and determines corresponding human judging results (Step S3). Then, the test data, the trend line graphs and the human judging results are inputted into the machine learning model, and a learning process is performed (Step S4). Then, a step S5 is performed to judge whether the number of samples in the learning process reaches a predetermined threshold value. If the number of samples in the learning process reaches the predetermined threshold value, the machine learning model generates auxiliary judging results according to the corresponding test data and the corresponding trend line graphs (Step S6).

The auxiliary testing method is applied to the product testing system 100. In an embodiment, the auxiliary testing method is implemented through the software execution. For example, a testing program is stored in the computer 12 for implementing the auxiliary testing method. When the testing program is executed, the testing process of the test fixture 11 on the plural under-test products is monitored and the machine learning model is controlled. The operator can realize the testing result from the test fixture 11 through the computer 12. In addition, the operator can input associated testing commands or judging commands through the computer 12.

In the steps S1 and S2, the test fixture 11 tests the plural under-test products to obtain the test data. The test data indicate the quality or operating performance of the corresponding under-test products. In addition, the test data are transmitted to the computer 12. According to the test data corresponding to the under-test products, the relevant testing program calculates the plural trend line graphs as shown in FIGS. 1A and 1B.

In an embodiment, the conventional application program for generating the trend line graphs is a part of the testing program of the present invention. That is, the conventional application program for generating the trend line graphs is integrated into the testing program of the present invention, and the conventional application program and the testing program of the present invention are simultaneously executed by the computer. Alternatively, the conventional application program for generating the trend line graphs and the testing program of the present invention are independently installed in the computer 12 but collaboratively operated.

When the testing program of the present invention is executed, a user operation interface (not shown) is shown on the computer (e.g., on a display screen of the computer 12). The operator can observe the trend line graphs corresponding to the under-test products through the user operation interface. After observation and judgment, the operator may input the human judging results through the user operation interface. For example, the operator may select and click corresponding icons of the user operation interface to input the human judging results. Alternatively, the operator may use an input device (e.g., a keyboard or a mouse) of the computer 12 to input the human judging results.

In the step S3, the operator observes and judges the contents of the trend line graphs according to subjective judgment and determines the corresponding human judging results. Like the conventional technologies, the operator makes the subjective judgment after observing the entire of the displayed contents of the trend line graphs. In an embodiment, each human judging result is a first quality type or a second quality type. That is, the quality is classified according to dichotomy or polarization. If the shape or curve of the trend line graph increases slowly and the trend line graph has no abrupt segment change or noise, the under-test product is qualified and the sensor passes the test. Whereas, if the shape or curve of the trend line graph does not increase slowly or the trend line graph has any abrupt segment change or noise, the under-test product is unqualified and the sensor fails in the test.

As mentioned above, the first quality type denotes that the under-test product is qualified, and the second quality type denotes that the under-test product is unqualified. For allowing the operator to sequentially input the corresponding human judging results on the user operation interface, the user operation interface contains two selective icons corresponding to the first quality type and the second quality type. It is noted that the example of the user operation interface in response to the execution of the testing program is not restricted.

In accordance with another feature of the present invention, the human judging results are used as the targets or bases in the training and learning process of the machine learning model. Preferably, in the initial stage of the testing process, the standard products are used as golden samples. The standard products have been verified, or the quality of the standard products can be easily recognized. Consequently, the trend line graphs are standard learning objects. In other words, the standard samples can facilitate the machine learning model to judge and induct the types of the trend line graphs corresponding to the first quality type or the second quality type.

In the step S4, the test data, the trend line graphs and the human judging results are inputted into the machine learning model after generation. By using the human judging results as target values, the machine learning model performs a learning process. For example, the machine learning model is a neural network model. In this stage, the results to be used as the judgment references are not shown. However, the output data is generated according to the initial weights of the neural network. In the learning process, the difference between the output value and the target value (i.e., the human judging result) is compared. If there is the difference, the neural network adjusts the weights of the connection lines according to the target value.

For example, a digitalized trend line graph is composed of plural pixels. Consequently, the neural network model can realize the shape or curve of the trend line graph according to the contents and the distribution of the pixels. In an embodiment, the trend line graphs have the same size, and the pixels have the same size. In addition, the neutrons of the input layer 21 as shown in FIG. 3 are specially designed to match the pixels of the trend line graph. That is, the value of each pixel is used as the input data and inputted into the corresponding neutron of the input layer 21.

In the above embodiment, the input data are inducted according to the weights of the connection lines of the network, and the output results of the output layer 23 are limited to be the first quality type or the second quality type. In accordance with the existing technologies, the result of the learning process is the adjusted result according to the weights of the connection lines of the network after plural input data are judged and inducted. When the number of samples in the learning process reaches a predetermined threshold value, the machine learning model generates auxiliary judging results. For example, the predetermined threshold value is 20. That is, after 20 under-test products are tested and 20 trend line graphs are generated, the operator determines 20 human judging results. Generally, as the number of samples in the training and learning process increases, the result of judging, inducing and predicting the input data is more accurate and more expectable.

In the step S5, if the number of samples in the learning process does not reach the predetermined threshold value, the machine learning model has to continuously perform the training and learning process. That is, the above steps are repeatedly done to test more under-test products. Whereas, in the steps S5 and S6, if the number of samples in the learning process reaches the predetermined threshold value, the machine learning model determines the weights of the first quality type and the second quality type corresponding to the test data and the trend line graph of the under-test product. That is, the machine learning model generates the output data according to the weights of the connection lines of the network. Under this circumstance, the corresponding auxiliary judging result is generated. Similarly, in an embodiment, the auxiliary judging result includes the first quality type or the second quality type.

As mentioned above, the auxiliary judging results are provided as references for assisting the operator in judging the testing result. That is, the auxiliary judging results are used for assistance, prompt or recommendation, and not the final judging results. The auxiliary judging result generated at this time is used as a reference for the operator. In addition, the operator may observe whether the auxiliary judging result is different from the inputted human judging result. Meanwhile, the user operation interface is shown again for allowing the operator to make the confirmation and selection of the final judgment.

Consequently, the auxiliary testing method further comprises the following steps. The machine learning model compares one of the auxiliary judging results with the corresponding human judging result. If the auxiliary judging result is different from the corresponding human judging result, a prompt message is generated. The operator generates a modified judging result in response to the prompt message, and inputs the modified judging result into the machine learning model for further adjustment.

The prompt message is a text, a picture or a sound issued from the computer 12 (e.g., through a display screen or a loudspeaker) for prompting the operator that the judging result of the operator and the judging result of the machine learning model are different. According to the modified judging result, the auxiliary judging result is accepted or not accepted. For example, if the operator judges that the judging result of the machine learning model is correct, the original human judging result is discarded and the auxiliary judging result is accepted. Whereas, if the operator judges that the judging result of the machine learning model is wrong and the judging result of the operator is correct, the operator notifies the machine learning model that the auxiliary judging result is not accepted. That is, the backward-propagation is performed.

Consequently, the auxiliary testing method further comprises a step of allowing the machine learning model to adjust the weights of the first quality type and the second quality type corresponding to the test data and the trend line graphs according to the modified judging result. That is, the weights of the connection lines of the network are adjusted by using the modified judging result as the newest target value.

In accordance with another feature of the present invention, the machine learning model (e.g., the neural network model) is capable of displaying the judging result of the under-test product in the step S6 and also continuously performing the training and learning process. In other words, the machine learning model provides the output data for reference, and the human judging result or the modified judging result inputted by the operator can be used as the re-training and re-learning target value of the machine learning model. Consequently, in the learning process, the new data is continuously inputted, the prediction result is outputted, and the weights are adjusted according to the target value. As long as the functional circuit test in the production line is continuously performed, the learning process will not be ended.

It is noted that numerous modifications and alterations may be made while retaining the teachings of the invention. For example, in another embodiment, the human judging results corresponding to the under-test products are no longer generated by the operator after the number of samples in the learning process reaches the predetermined threshold value. In addition, the auxiliary judging result generated by the machine learning model is firstly generated, and then the final judgment is determined by the operator. Under this circumstance, the human judging result generated by this method directly agrees with the auxiliary judging result, or the auxiliary judging result is directly modified.

In the above embodiment, the first quality type and the second quality type of the human judging result or the auxiliary judging result are defined according to dichotomy or polarization. That is, the product is roughly determined as the qualified product or the unqualified product according to one grade. However, in case that the testing process generates a non-linear testing result, the testing result is usually unable to be precisely classified according to the dichotomy. In accordance with the present invention, each of the first quality type and the second quality type contains more grade items under the concepts of the dichotomy. Consequently, the classification efficacy is enhanced.

For example, the first quality type representative of the qualified product includes two grades “Excellent” and “Good”, and the second quality type representative of the unqualified product includes two grades “Poor” and “Bad”. Consequently, the operator has more choices about the judging result of the under-test product. In addition, the machine learning model is helpful for the more detailed training and learning process.

As mentioned above, the prediction result of the machine learning model is possibly different from the human judging result. Moreover, in case that the number of data is enough, the neutral network is effective to learn and modify the weights. However, if the data amount to be learnt is very large, the learning process is time-consuming. If the data amount to be learnt is very small, the prediction accuracy is low. For achieving the effective prediction result, more experiments should be performed in the testing process to acquire the optimized efficacy of the machine learning model.

Consequently, the auxiliary testing method of the present invention further comprises the following steps. The machine learning model generates a successful judging probability according to the auxiliary judging result, the corresponding human judging result and the corresponding modified judging result. Then, the predetermined threshold value is adjusted according to the successful judging probability.

For example, if the predetermined threshold value is 20 and the subsequent prediction is often erroneous (i.e., the successful judging probability is low), the predetermined threshold value is increased to 100 for example. When the number of samples in the learning process reaches the predetermined threshold value, the machine learning model generates auxiliary judging results. Consequently, the machine learning model can effectively judge and learn the trend line graphs corresponding to the qualified products and the trend line graphs corresponding to the unqualified products.

From the above descriptions, the present invention provides a product testing system with an auxiliary judging function and an auxiliary testing method. When compared with the conventional technologies, the present invention has the following benefits. Firstly, in case that the number of samples is sufficient, the auxiliary judging results generated by the machine learning model have certain credibility. In addition to the subjective judgment of the operator, the prediction generated by the machine learning model also provides an objective reference while reducing the working time and the fabricating cost. Secondly, even if the testing process needs a large amount of working time and huge workload, the assistance of the machine learning model is helpful to avoid misjudgment and objectively differentiate the details of different shapes or curves. Thirdly, the technologies of the present invention provide a good foundation for the development of future intelligent production lines and artificial intelligence unmanned factories.

In other words, the product testing system and the auxiliary testing method of the present invention can overcome the drawbacks of the conventional technologies while achieving the objects of the present invention.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. An auxiliary testing method for a product testing system and plural under-test products, the product testing system comprising a computer and a test fixture, the computer being in communication with the test fixture, the computer having a machine learning model, the auxiliary testing method comprising steps of:
the test fixture testing the plural under-test products sequentially, and generating corresponding test data to the computer;
the computer generating plural trend line graphs corresponding to the test data;
the operator judging contents of the trend line graphs, and determining corresponding human judging results;
inputting the test data, the trend line graphs and the human judging results into the machine learning model, and performing a learning process; and
if the number of samples in the learning process reaches a predetermined threshold value, the machine learning model generating auxiliary judging results according to the corresponding test data and the corresponding trend line graphs.

2. The auxiliary testing method according to claim 1, wherein a testing program is stored in the computer, and the auxiliary testing method further comprises a step of executing the testing program to control the machine learning model.

3. The auxiliary testing method according to claim 1, wherein each of the human judging results or each of the auxiliary judging results is a first quality type or a second quality type, wherein the first quality type or the second quality type contains at least one grade item.

4. The auxiliary testing method according to claim 3, further comprising a step of allowing the machine learning model to determine weights of the first quality type and the second quality type corresponding to the test data and the trend line graphs, thereby generating the corresponding auxiliary judging results.

5. The auxiliary testing method according to claim 1, further comprising steps of:
the machine learning model comparing one of the auxiliary judging results with the corresponding human judging result;
if the auxiliary judging result is different from the corresponding human judging result, generating a prompt message; and
the operator generating a modified judging result in response to the prompt message, and inputting the modified judging result into the machine learning model for further adjustment.

6. The auxiliary testing method according to claim 5, wherein each of the human judging results or each of the auxiliary judging results is a first quality type or a second quality type, and the first quality type or the second quality type contains at least one grade item, wherein the auxiliary testing method further comprises a step of allowing the machine learning model to adjust the weights of the first quality type and the second quality type corresponding to the test data and the trend line graphs according to the modified judging result.

7. The auxiliary testing method according to claim 5, further comprising steps of:
the machine learning model generating a successful judging probability according to the auxiliary judging result, the corresponding human judging result and the corresponding modified judging result; and
adjusting the predetermined threshold value according to the successful judging probability.

8. The auxiliary testing method according to claim 1, wherein the machine learning model includes a neural network model or an artificial neural network model.

9. A product testing system with an auxiliary judging function and configured for testing plural under-test products, the product testing system comprising:
a test fixture testing the plural under-test products sequentially, and generating corresponding test data; and
a computer in communication with the test fixture, wherein the computer has a machine learning model that receives the test data from the test fixture and generates plural trend line graphs corresponding to the test data,
wherein after an operator judges contents of the trend line graphs and determines corresponding human judging results, the test data, the trend line graphs and the human judging results are inputted into the machine learning model and a learning process is performed, wherein when the number of samples in the learning process reaches a predetermined threshold value, the machine learning model generates auxiliary judging results according to the corresponding test data and the corresponding trend line graphs.

10. The product testing system according to claim 9, wherein each of the human judging results or each of the auxiliary judging results is a first quality type or a second quality type, wherein the first quality type or the second quality type contains at least one grade item.

11. The product testing system according to claim 10, wherein the machine learning model determines weights of the first quality type and the second quality type corresponding to the test data and the trend line graphs so as to generate the corresponding auxiliary judging results.

12. The product testing system according to claim 9, wherein the machine learning model compares one of the auxiliary judging results with the corresponding human judging result, wherein if the auxiliary judging result is different from the corresponding human judging result, a prompt message is generated, wherein the operator generates a modified judging result in response to the prompt message, and inputs the modified judging result into the machine learning model for further adjustment.

13. The product testing system according to claim 12, wherein each of the human judging results or each of the auxiliary judging results is a first quality type or a second quality type, and the first quality type or the second quality type contains at least one grade item, wherein the machine learning model adjusts the weights of the first quality type and the second quality type corresponding to the test data and the trend line graphs according to the modified judging result.

14. The product testing system according to claim 12, wherein the machine learning model generates a successful judging probability according to the auxiliary judging result, the corresponding human judging result and the corresponding modified judging result, and the predetermined threshold value is adjusted according to the successful judging probability.

15. The product testing system according to claim 9, wherein the machine learning model includes a neural network model or an artificial neural network model.
